(19) United States
(12) Patent Application Publication
(10) Pub. No.: US 2012/0293961 A1
(43) Pub. Date: Nov. 22, 2012

(54) LIGHTING APPARATUS

(75) Inventors: Shoji Yamamoto, Osaka-shi (JP); Hideyuki Akao, Osaka-shi (JP)

(73) Assignee: SHARP KABUSHIKI KAISHA, Osaka-shi, Osaka (JP)

(21) Appl. No.: 13/522,117

(22) PCT Filed: Feb. 1, 2011
(86) PCT No.: PCT/JP2011/051973

§ 371 Date: Jul. 13, 2012

(30) Foreign Application Priority Data
Feb. 8, 2010 (JP) 2010-025750

(51) Int. Cl. F21V 29/00; H05K 7/20

(52) U.S. Cl. 361/714

(57) ABSTRACT

A lighting apparatus includes a light source, a power supply circuit supplying power to the light source, a heat radiating section made of electrical insulating material and radiating heat from the power supply circuit to outside air, and a heat conducting section conducting heat from the power supply circuit to the heat radiating section, and the heat radiating section and the heat conducting section are thermally connected. A weight reduction of the lighting apparatus is realized and a heat conduction from the heat conducting section to the heat radiating section is improved.

This application is the national phase under 35 U.S.C. §371 of PCT International Application No. PCTJP2011/051973 which has an International filing date of Feb. 1, 2011 and designated the United States of America.

### BACKGROUND

1. Technical Field

The present invention relates to a lighting apparatus including a heating body, a heat conducting section for conducting heat from the heating body, and a heat radiating section for radiating heat from the heat conducting section.

2. Description of Related Art

A lighting apparatus generally accommodates inside the apparatus heat-generating components (heating bodies) such as a light source, a power supply section for supplying electrical energy to the light source. Unfortunately, the performance of a heat-generating component such as a light source like a light emitting diode (hereinafter referred to as the “LED”) and an electronic component constituting a power supply section cannot be ensured when the temperature of the heat-generating component increases due to the heat-generation thereof. Additionally, in view of the safety reason, it is undesirable that the temperature of the outer surface of the lighting apparatus increases. Therefore, it has been proposed that a lighting apparatus is able to radiate heat to the air outside of the lighting apparatus from the heat-generating component (for example, Japanese Patent Application Laid-Open 2008-186776).

A lighting apparatus disclosed in Patent Document 1 includes a light source section 110 having a light source 111, a power supply section 130 for lighting the light source 111, a power terminal block 140 for supplying electrical energy to the power supply section 130, and a main body 120 to which the light source section 110, the power supply section 130 and the power terminal block 140 are installed. The lighting apparatus is installed on ceiling by a supporting tool 150 composed of spring material and located at the outer periphery of the main body 120 such that the light source section 110 is close to an installation aperture. The lighting apparatus is used as a so-called downlight (see FIG. 1). The main body 120 is approximately cylindrical in shape and has a disk-shaped supporting section 121 for supporting the light source section 110 installed at one-end and a disk-shaped attachment section 122 forming a space for accommodating both the supporting section 121 and the power supply section 130.

A circuit board 112 on which the light source 110 is mounted is fixed on one surface of the supporting section 121 by nails in such a manner that the circuit board 112 comes in contact with the one surface. A circuit board 131 of the power supply section 130 is fixed on the other surface of the supporting section 121 by nails in such a manner that the periphery of the circuit board 131 comes in contact with a supporting step portion formed integratedly with the supporting section 121. Since the main body 120 is made of aluminum die-casting, the main body 120 can also be functioned as a heat radiating section for radiating heat from the light source 111 and the power supply section 130.

### SUMMARY

The performance of heat radiation can be improved by constituting a heat radiating section by using metal such as aluminum, but the problem of the weight increase of lighting apparatus arises. In order to reduce the weight of lighting apparatus, constituting a heat radiating section by utilizing light material such as resin with better performance of heat radiation instead of utilizing metal is considered. Patent Document 1 also discloses the matter of utilizing synthetic resin such as resin with high thermal conductivity as the material for the main body 120.

In the main body 120 of the lighting apparatus related to Patent Document 1, only the periphery of the circuit board 131 of the power supply section 130 comes into contact with the main body 120, a heat conducting area on which heat is conducted from the power supply section 130 cannot be fully obtained. Generally, since the efficiency of heat conduction of resins with high thermal conductivity is lower than that of a metal, if the material for the main body 120 is merely modified, then the heat generated in the power supply section 130 cannot be fully conducted to the main body 120 so that heat radiation cannot be fully performed.

The present invention has been made in view of such circumstances. It is an object to provide a lighting apparatus, which can conduct heat efficiently from a heating body to a heat radiating section.

A lighting apparatus related to the present invention includes a light source, a power supply circuit supplying power to the light source, a heat radiating section, made of electrical insulating material, radiating heat from the power supply circuit accommodated inside to outside air, and a heat conducting section conducting heat from the power supply circuit to the heat radiating section, and the heat radiating section and the heat conducting section are thermally connected.

In the present invention, since the heat radiating section which is made of electrical insulating material and radiates the generated heat from the power supply circuit to the outside air and the heat conducting section which conducts heat from the power supply circuit to the heat radiating section are thermally connected, the heat conduction from the heat conducting section to the heat radiating section can be improved even if a heat radiating section made of resin with typically lower heat conduction efficiency is used for example.

A lighting apparatus related to the present invention includes a heating body such as a light source and a power supply circuit, a heat radiating section radiating heat from the heating body, and a heat conducting section conducting heat from the heating body to the heat radiating section, and at least a part of opposite surfaces of the heat conducting section and the heat radiating section is thermally connected so as to perform efficient heat conduction.

With regard to the present invention, the surface of the heat radiating section radiating the heat generated in the heating body and the opposite surface of the heat conducting section conducting the heat from the power supply circuit to the heat radiating section are thermally connected in at least a part in order to perform efficient heat conduction so that the range of the surface for performing heat conduction can be broadened. Since the conducted heat energy increases, the performance of heat conduction from the heat conducting section to the heat radiating section can be improved.

A lighting apparatus related to the present invention is characterized in that at least a part of the heat conducting section is buried in the heat radiating section.

With regard to the present invention, since the heat conducting section is buried in the heat radiating section, it is possible to broaden the heat conduction area of both the heat conducting section and the heat radiating section and increase the degree of adhesion. As the conducted heat energy increases, there is generated no gap between the heat conducting section and the heat radiating section and the heat resistance can be reduced so that it is possible to perform efficient heat conduction.

A lighting apparatus related to the present invention has a base, and the base is formed integratedly with the heat radiating section.

With regard to the present invention, by forming the base integratedly with the heat radiating section, the manufacturing process can be simplified since connecting tools such as nails are not utilized in the process.

A lighting apparatus related to the present invention is characterized in that the heat conducting section has a connecting section thermally connected to the power supply circuit and a conducting unit conducting heat from the power supply circuit to the heat radiating section.

With regard to the present invention, the heat conducting section is composed of the connecting section thermally connected to the power supply circuit and the conducting unit conducting heat from the power supply circuit to the heat radiating section so that heat conducting area in which the heat from the power supply circuit is conducted to the heat radiating section can be broadened thanks to the conducting unit. It is possible to reduce heat resistance in the heat conducting section and suppress temperature rising of the heat conducting section.

A lighting apparatus related to the present invention is characterized in that the heat conducting section has a tubular section accommodating the power supply circuit inside, a connecting section installed on the tubular section and thermally connected to the power supply circuit, and a protruding section protruded on the outer surface of the tubular section, and the heat radiating section covers both the outer surface of the tubular section and the protruding section.

With regard to the present invention, the heat conducting section includes the tubular section accommodating the power supply circuit inside, the connecting section thermally connected to the tubular section and supporting the power supply circuit, and the protruding section protruded on the outer surface of the tubular section, and installs the heat radiating section so as to cover both the outer surface of the tubular section and the protruding section of the heat conducting section. Since both of the outer surface of the tubular section and the surface of the protruding section adhere to the heat radiating section, a heat conduction area in which heat conduction is efficient can be broadened. The heat from the power supply circuit is conducted to both the tubular section and the protruding section through the connecting section so that the heat can be conducted efficiently to the heat radiating section installed with adhering to both the tubular section and the protruding section, and the heat generated in the power supply circuit can be fully radiated from the heat radiating section.

A lighting apparatus related to the present invention is characterized in that the heat conducting section has a tubular section accommodating the power supply circuit inside and is thermally connected to the power supply circuit on the inner surface of the tubular section, and the heat radiating section covers the outer surface of the heat conducting section.

With regard to the present invention, the heat conducting section has the tubular section that can accommodate the power supply circuit inside. The heat from the power supply circuit can be efficiently to the heat conducting section at the inner surface of the tubular section by thermally connecting the heat conducting section to the power supply circuit while accommodating the power supply circuit. By installing the heat radiating section so as to cover the outer surface of the heat conducting section, the heat conduction area of both the heat conducting section and the heat radiating section can be broadened, Since the heat radiating section adheres to the outer surface of the heat conducting section, heat conduction can be efficiently performed from the heat conducting section to the heat radiating section.

According to the present invention, heat can be efficiently conducted from the heating body to the heat radiating section.

The above and further objects and features will more fully be apparent from the following detailed description with accompanying drawings.

### BRIEF DESCRIPTION OF THE DRAWINGS

FIG. 1 is a schematic longitudinal sectional view of a lighting apparatus related to the prior art.

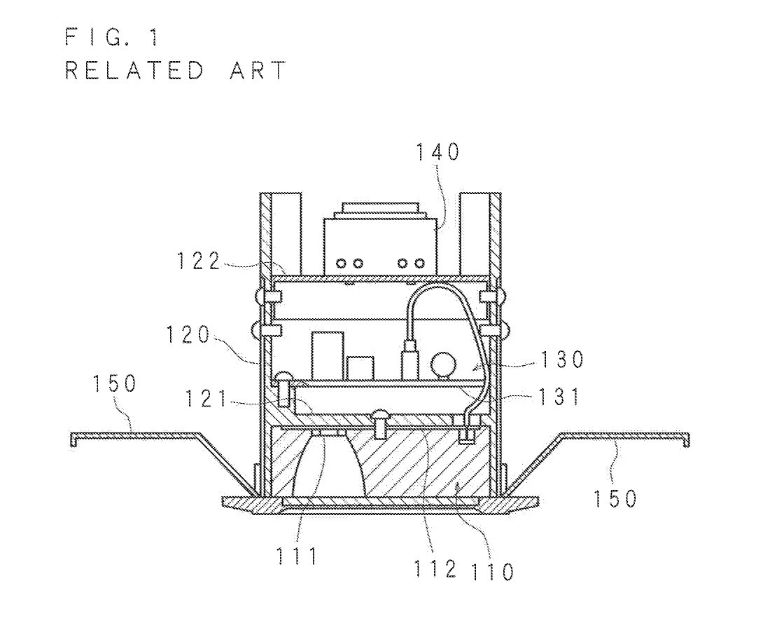

FIG. 2 is a schematic outline view of a lighting apparatus related to a first embodiment of the present invention.

FIG. 3 is a schematic exploded perspective view of the lighting apparatus related to the first embodiment of the present invention.

FIG. 4 is a schematic cross sectional view of the lighting apparatus related to the IV-IV line of FIG. 2.

FIG. 5 is a schematic longitudinal sectional view of the lighting apparatus related to the V-V line of FIG. 4.

FIG. 6 is a schematic longitudinal sectional view of the lighting apparatus related to the VI-VI line of FIG. 4.

FIG. 7 is a schematic enlarged view of a heat exchanger plate in the first embodiment of the present invention.

FIG. 8 is an explanatory drawing of the formation of a heat radiating section in the first embodiment of the present invention.

FIG. 9 is an explanatory drawing of the formation of the heat radiating section in the first embodiment of the present invention.

FIG. 10 is a schematic cross sectional view of a lighting apparatus related to a second embodiment of the present invention.

FIG. 11 is a schematic longitudinal sectional view of the lighting apparatus related to the second embodiment of the present invention.

### DETAILED DESCRIPTION

The present invention will be described below in detail as an example of a bulb-type lighting apparatus based on drawings illustrating embodiments of the present invention.

### First Embodiment

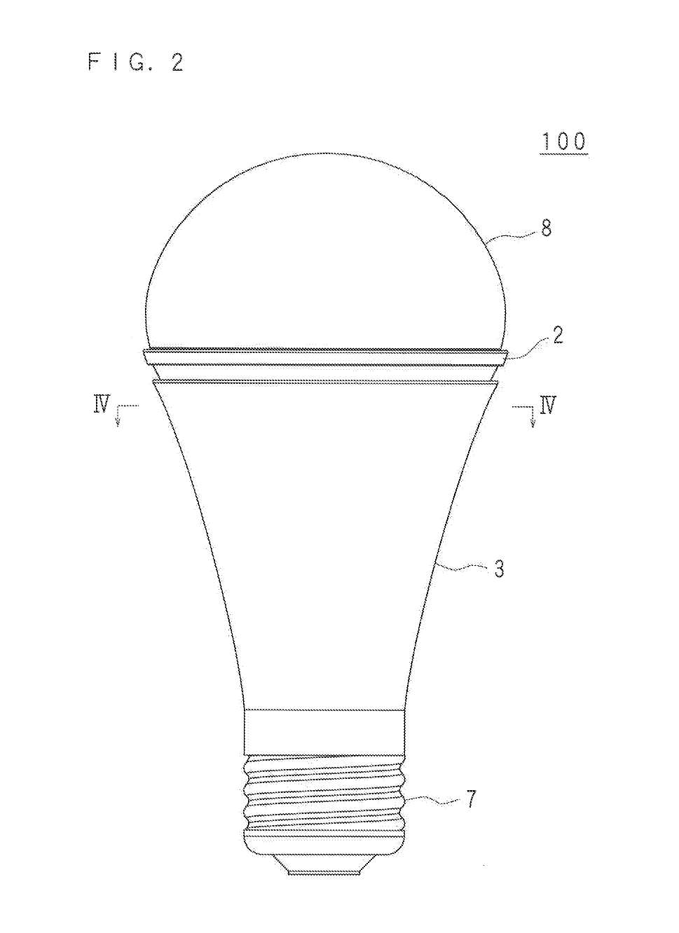

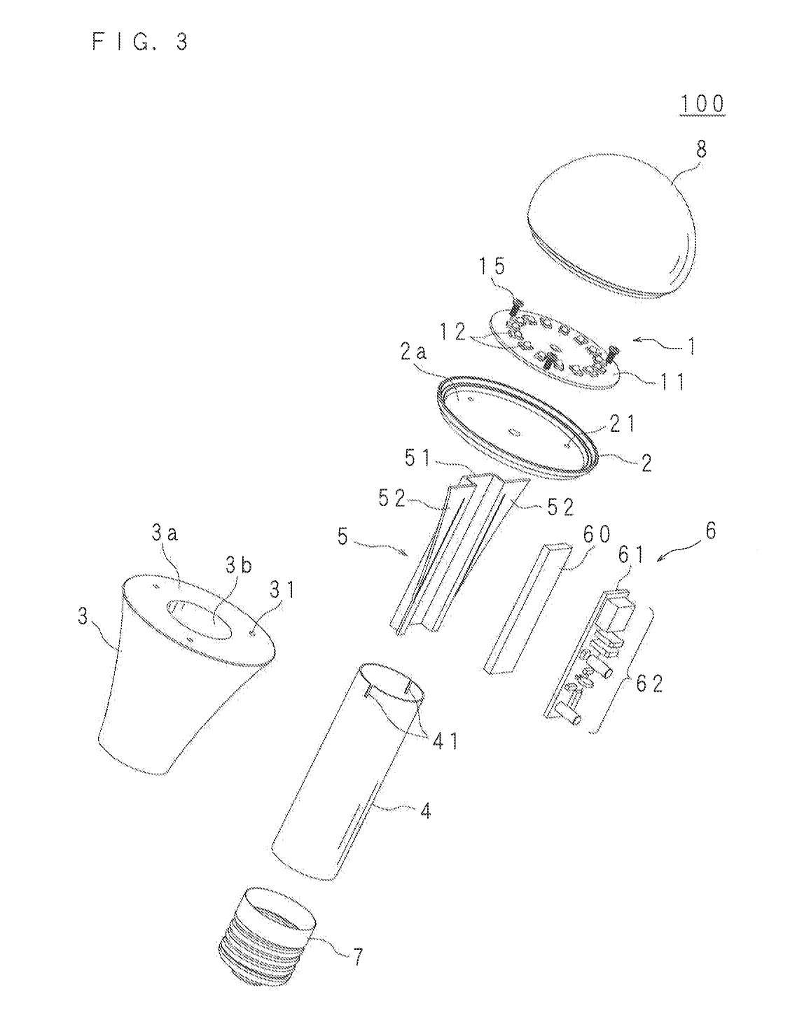

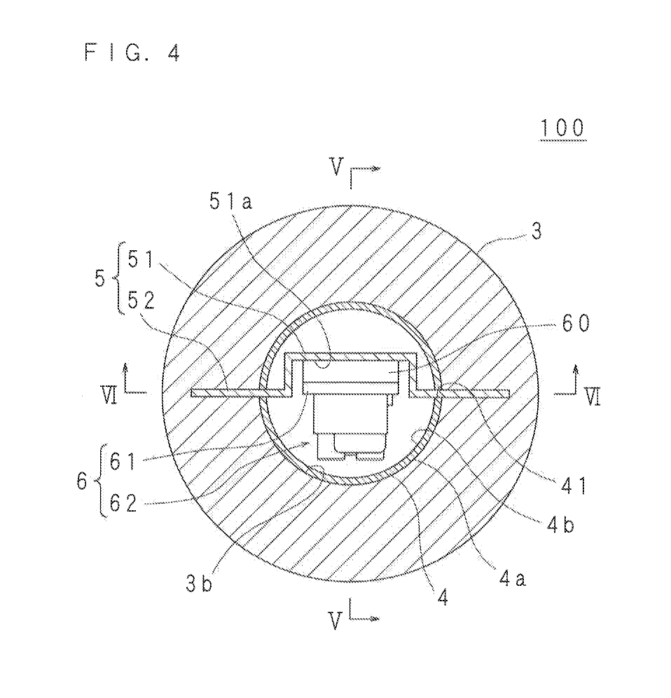

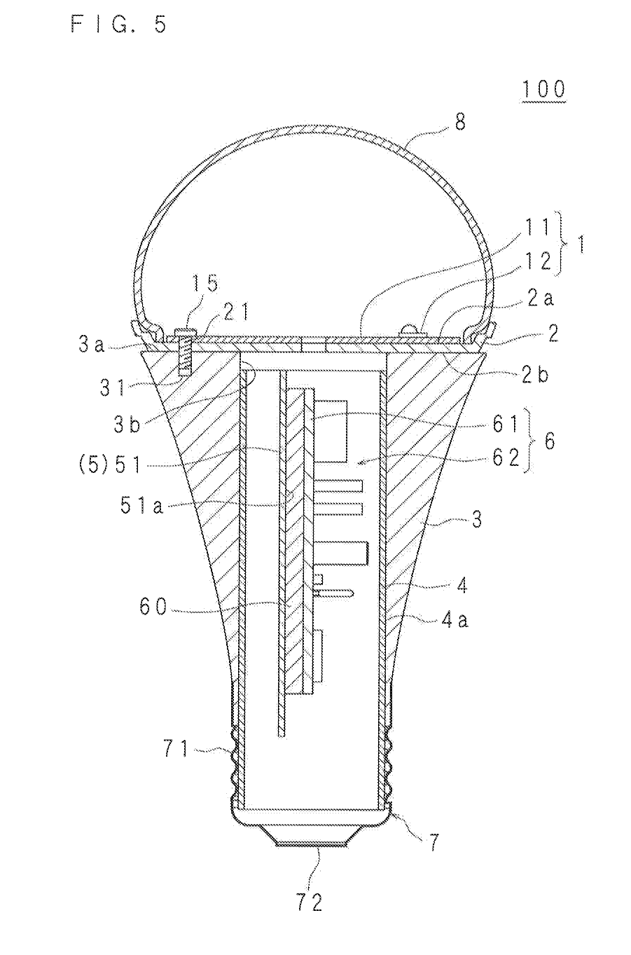

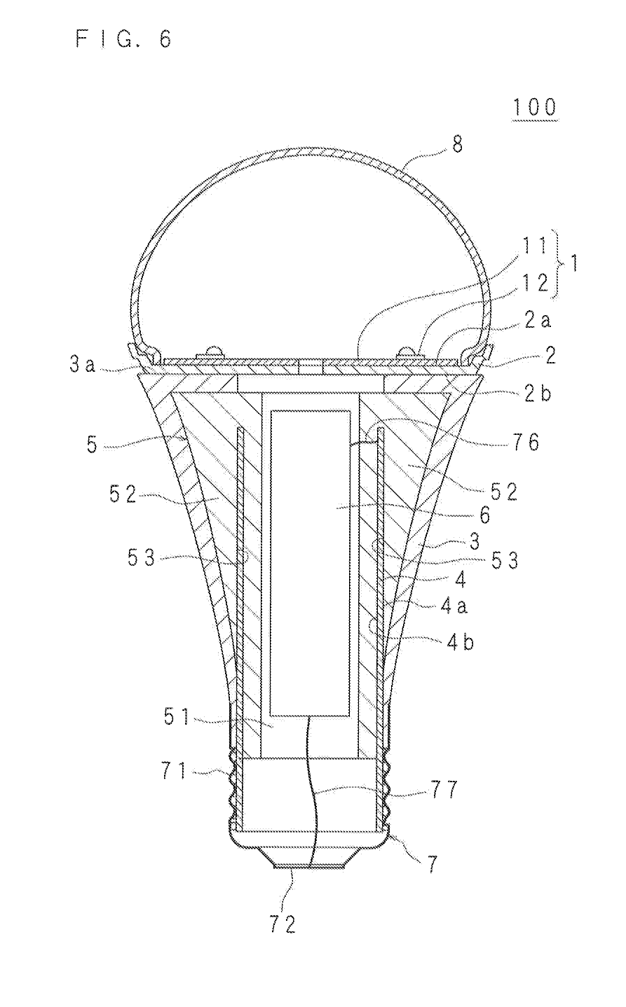

FIG. 2 is a schematic outline view of a lighting apparatus 100 related to the first embodiment of the present invention. FIG. 3 is a schematic exploded perspective view of the lighting apparatus 100 related to the first embodiment of the present invention. FIG. 4 is a schematic cross sectional view of the lighting apparatus 100 related to the IV-IV line of FIG. 2. FIG. 5 is a schematic longitudinal sectional view of the lighting apparatus 100 related to the V-V line of FIG. 4. FIG. 6 is a schematic longitudinal sectional view of the lighting apparatus 100 related to the VI-VI line of FIG. 4.

As shown in FIG. 3, the lighting apparatus 100 related to the first embodiment includes a light source module 1 in which a plurality of LEDs 12 as light sources are mounted, a dome-shaped cover 8 for covering the light source module 1; a heat radiator plate 2 to which the light source module 1 is attached, a power supply circuit 6 supplying electrical energy to drive the light source module 1; a heat exchanger plate 5 on which the power supply circuit 6 is installed; a heat conducting tube 4 fitted together with the heat exchanger plate 5 and accommodating the power supply circuit 6; a heat conducting sheet 60 provided between the power supply circuit 6 and the heat exchanger plate 5; a heat radiating section 3 accommodating the heat exchanger plate 5, the power supply circuit 6, the heat conducting sheet 60 and the heat conducting tube 4, the heat radiator plate 2 being installed between the cover 8 and the heat radiating section 3; and a base 7 connected to the heat radiating section 3 at the opposite side of the heat radiator plate 2.

As shown in both FIG. 3 and FIG. 5, with regard to the light source module 1, a plurality of LEDs 12 as light sources are mounted on one surface of a disc-shaped LED substrate 11. For example, the LED 12 is a surface-mount type LED.

The light source module 1 is attached to the disc-shaped heat radiator plate 2. The heat radiator plate 2 is a good heat conductor, for example, made of metal such as aluminum. With regard to the light source module 1, the other surface at the non-mounting side of the LED substrate 11 is fixed to one surface 2a of the heat radiator plate 2.

The heat radiator plate 2 is attached to the heat radiating section 3 such that the other surface 2b faces to the heat radiating section 3. The heat radiating section 3 forms the shape of a thick-walled cylinder that has the outward form of a truncated cone of which the diameter is expanded from the side of the base 7 towards the side of the cover 8 in a gradual manner. To coordinate tapped holes (not shown in figures) of the LED substrate 11, tapped holes 21 of the heat radiator plate 2 and tapped holes 31 located at an enlarged surface 3a at the side of the cover 8 of the heat radiating section 3, both of the source light module 1 and the heat radiator plate 2 are mounted on the surface 3a at the side of the cover 8 of the heat radiating section 3, and screws 15 are screwed to the tapped holes, so both of the light source module 1 and the heat radiator plate 2 are fixed to the heat radiating section 3.

In the present embodiment, the heat radiating section 3 is made of resin with excellent heat radiant and electrical insulating property, also known as heat radiation resin. The heat radiation resin has the electrical insulating property. The thermal conductivity of heat radiation resin is, for example, about 1 to 70 (W/m·K). The heat radiation resin is made of synthetic resin having, for example, PBT (Polybutyleneterephtalate) as the base. Additionally, the heat radiation resin having the electrical insulating property is preferable; however, it is not limited to utilize the synthetic resin including PBT.

Since the whole surface of the LED substrate 11 comes into contact with that of the heat radiator plate 2 and the whole surface of the heat radiator plate 2 comes into contact with that of the heat radiating section 3 respectively, adequate heat transfer area can be created. Accordingly, the heat generated in the LED 12 as a heating body is efficiently conducted to the heat radiator plate 2 through the LED substrate 11. A part of the conducted heat is radiated to the air outside of the lighting apparatus 100 from the periphery of the heat radiator plate 2, and the remainder of heat is efficiently conducted to the heat radiating section 3 from the heat radiator plate 2 and radiated to the air outside of the lighting apparatus 100 from the heat radiating section 3. Since the heat is radiated from both the heat radiator plate 2 and the heat radiating section 3, cooling to the necessary temperature for ensuring the predetermined performance and durability of the LED 12 can be done. Additionally, it is desirable to install a thermal conduction sheet or grease with good thermal conductivity between the LED substrate 11 and the heat radiator plate 2 as well as between the heat radiator plate 2 and the heat radiating section 3.

Inside the heat radiating section 3, the heat conducting tube 4 and the heat exchanger plate 5 as the heat conducting sections conduct heat to the heat radiating section 3 from a heating body such as the LED 12 and the power supply circuit 6. The heat conducting tube 4 and the heat exchanger plate 5 are good heat conductors made of metal such as aluminum.

A notch 41 is formed into two parts at one end of the cylindrical-shaped heat conducting tube 4. The notch 41 is notched in rectangular shape longitudinally from the periphery at the side of the cover 8 of the heat conducting tube 4. The width of the notch 41 is substantially same as the thickness of the heat exchanger plate 5, which is engaged with the notch 41. Additionally, the power supply circuit 6 is accommodated inside the heat conducting tube 4. The heat conducting tube 4 forms a part of accommodating section to provide a space for housing the power supply circuit 6.

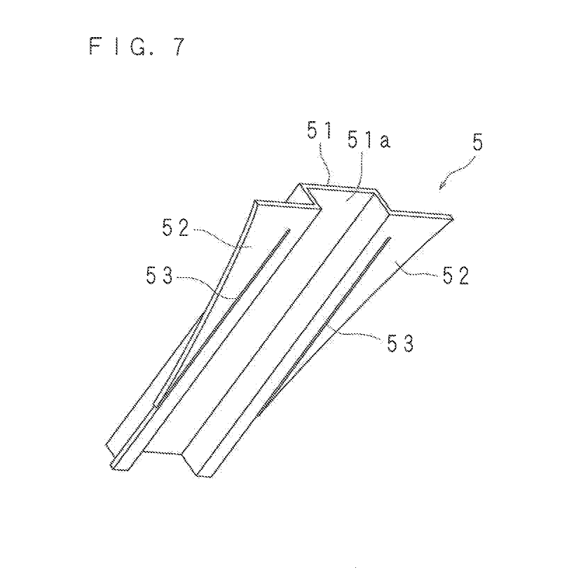

FIG. 7 is a schematic enlarged view of the heat exchanger plate 5 in the present embodiment. The heat exchanger plate 5 includes a rectangular plate-shaped connecting plate section 51 having a rectangular-shaped connecting plane 51a as a connecting section thermally connected to the power supply circuit 6, and two fins 52 connected consecutively at both ends of the long sides of the connecting plate section 51 and extending in spaced side by side relation to each other in parallel. Two fins 52 form the shapes of which the widths expands from the side of the base 7 to the side of the cover 8 along the outline form of the heat radiating section 3 as the outer coat of the lighting apparatus 100. In other words, two fins 52 form the shapes of trapezoids of which the widths expands from the side of the base 7 towards the side of the cover 8 in the longitudinal direction. As shown in both FIG. 6 and FIG. 7, a slit 53 forms a length up to the appropriate size along the longitudinal direction of each of the fins 52 from the end of the base 7. The width of the slit 53 is substantially same as the thickness of the heat conducting tube 4, which is engaged with the slit 53.

This heat exchanger plate 5 is integrated into the heat conducting tube 4 and thermally connected to each other, by putting this heat exchanger plate 5 into the heat conducting tube 4 longitudinally after aligning the position of the slit 53 with the position of the notch 41 of the heat conducting tube 4. As shown in FIG. 4, with regard to the integrated status, the most part of the fin 52 of the heat exchanger plate 5 is protruded in a radial direction of the heat conducting tube 4 from the outer surface 4a of the heat conducting tube 4; in other words, the most part of the fin 52 corresponds to the protruding section protruded on the outer surface of the tubular section of the heat conducting section. The width of the notch 41 of the heat conducting tube 4 and the width of the slit 53 of the heat exchanger plate 5 are substantially same as the thickness of the engaged heat exchanger plate 5 and the engaged heat conducting tube 4; therefore, the engaged heat exchanger plate 5 and the heat conducting tube 4 are being thermally connected to each other across the total length of the fin 52 of the heat exchanger plate 5 longitudinally.

Accordingly, the heat, which is conducted from the power supply circuit 6 to the heat exchanger plate 5, can also be efficiently conducted from the heat exchanger plate 5 to the heat conducting tube 4. The diameter of the heat conducting tube 4 and the shape of the connecting plate section 51 of the heat exchanger plate 5 are appropriately determined for making the power supply circuit 6 close to the inner surface 4b of the heat conducting tube 4 as much as possible. Both of the heat conducting tube 4 and the fin 52 are conducting sections for conducting heat to the heat radiating section 3 from the power supply circuit 6. As mentioned below, the fin 52 is a part of the heat conducting section buried in the heat radiating section 3. As mentioned above, the fin 52 is the protruding section protruded on the outer surface of the tubular section.

The power supply circuit 6 includes a rectangular-plate shaped power supply circuit substrate 61 and a plurality of power supply circuit components 62 mounted on the power supply circuit substrate 61. The power supply circuit components 62 includes a diode bridge that performs a full-wave rectification of AC current supplied from an external AC power supply, a transformer that transforms a rectified power voltage to a determined voltage, a diode that is connected to both primary side and secondary side of the transformer, and an IC. The rectangular-plate shaped thermal conducting sheet 60 is interposed between the power circuit supply substrate 61 and the connecting plate section 51 of the heat exchanger plate 5. The power supply circuit 6 is thermally connected to the heat exchanger plate 5 through the thermal conducting sheet 60, so the heat from the power supply circuit 6 is indirectly conducted to the heat exchanger plate 5. The dimension and arrangement of the thermal conducting sheet 60 are appropriately determined according to the arrangement of the power supply circuit components 62. A good heat conductor having electrical insulating property is utilized as the thermal conducting sheet 60. For example, the thermal conducting sheet 60 is made of fire resistant silicon rubber with low degree of hardness. Additionally, grease having better thermal conduction property may be utilized instead of utilizing the thermal conducting sheet 60. Since the power supply circuit substrate 61 is electrically insulated and thermally connected to the heat exchanger plate 5, any configuration with better thermal conduction may be adopted in the present embodiment.

The base 7 is installed at the one end side of the heat radiating section 3. The base 7 has a bottomed cylindrical shape and includes a one-pole terminal 71 of which the cylindrical portion is threaded for screwing with a light-bulb socket, and an other-pole terminal 72 protruded from the bottom surface of the base 7. The one-pole terminal 71 is electrically insulated from the other-pole terminal 72. The outline form of the cylindrical portion of the base 7 forms the same shape as, for example, E17 or E26 screwed-type base. The other end part of the heat conducting tube 4, which is at the opposite side of the notch 41 of the heat conducting tube 4, is fitted into the base 7.

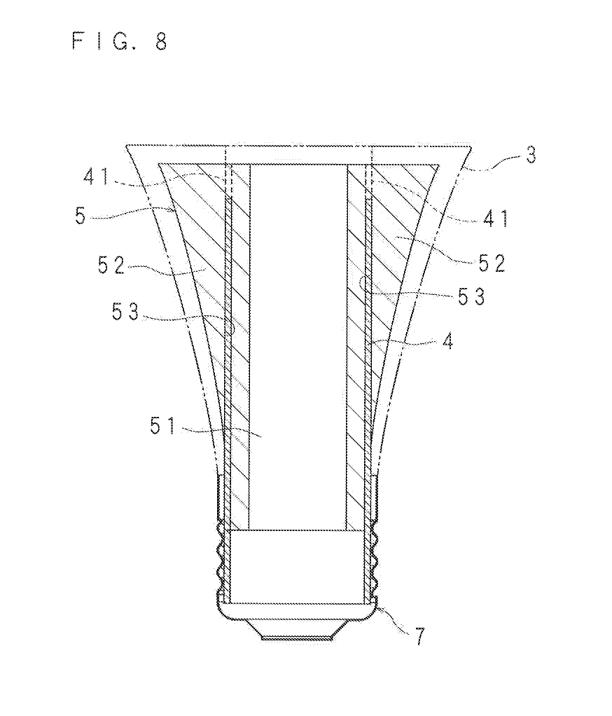

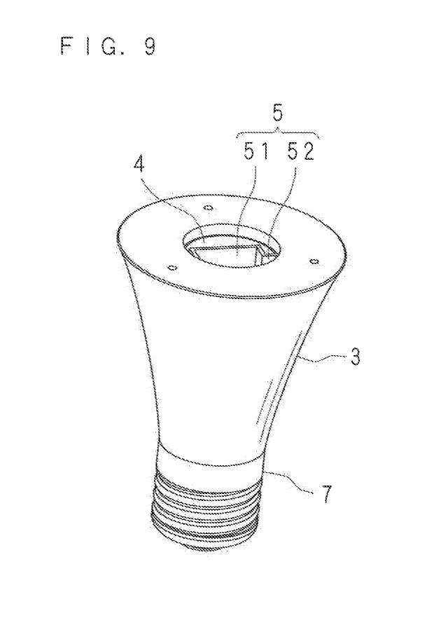

The method of forming the heat radiating section 3 is described below. Both of FIG. 8 and FIG. 9 are explanatory drawings of the formation of the heat radiating section 3 in the present embodiment. Firstly, for engaging the notch 41 of the heat conducting tube 4 with the slit 53 of the heat exchanger plate 5 mutually, the heat exchanger plate 5 is inserted into the heat conducting tube 4 such that the heat exchanger plate 5 is supported by the heat conducting tube 4 with engagement. Next, the heat conducting tube 4 is fitted into the base 7 in such a manner that the other end portion opposite to the notch 41 of the heat conducting section 4 is positioned inside the base 7 (see FIG. 8). While holding the heat conducting tube 4, the heat exchanger plate 5 and the base 7, a mold corresponding to the shape of the heat radiating section 3 as indicated by the dotted line in FIG. 8 is fitted. Then, the heat radiation resin with melted condition is flowed into the metal mould by using a mould injection machine and then the resin is solidified. The heat radiation resin is provided for covering the outer surface 4a of the heat conducting tube 4 accommodating the power supply circuit 6 and the portion of the fin 52 protruded from the outer surface 4a of the heat conducting tube 4, for burying the protruded portion into the heat radiating section 3, and for filling the gap between the inner surface of the base 7 and the outer surface 4a of the heat conducting tube 4. FIG. 9 shows the completed status of the formation of integrating the heat conducting tube 4, the heat exchanger plate 5 and the base 7 into the heat radiating section 3 after the heat radiating resin is solidified.

As described above, the heat conducting tube 4, the heat exchanger plate 5 and the base 7 are integrated in using the heat radiation resin (the heat radiating section 3). The heat radiating section 3 may be functioned as a connecting body for coupling the base 7 with the heat conducting section including the heat conducting tube 4 and the heat exchanger plate 5. Since the melted heat radiation resin is injected and solidified then the heat radiating section 3, the heat conducting tube 4, the heat exchanger plate 5 and the base 7 are formed in an integrated manner, the outer surface 4a of the heat conducting tube 4 and the fin 52 can be adhered to the heat radiating section 3 without creating gap; therefore, the increase of heat resistance due to air intervene can be prohibited so that the heat can be efficiently conducted from both of the heat conducting tube 4 and the heat exchanger plate 5 to the heat radiating section 3.

As the heat conducting section forms an shape such that the heat conducting tube 4 is able to house the power supply circuit 6 inside, it is possible to integrate the heat conducting section with the heat radiating section 3 by injection mould while ensuring a space for housing the power supply circuit 6. Moreover, the heat conducting section is constructed by the connecting plate 51 having a connecting surface 51a thermally connected to the power supply circuit 6 as a heat radiating body and both of the fin 52 and the heat conducting tube 4 as the conducting section for conducting heat to the heat radiating section 3 from the power supply circuit 6 thermally connected to the connecting plate 51. Since more heat transfer area can be ensured and the heat resistance of heat conducting section decreases, the heat generated from the heat radiating body can be dispersed in the heat conducting section so that the temperature rise of both the heat radiating body and the heat conducting section can be decreased. Since more heat transfer area of both of the heat conducting section and the heat radiating section can be ensured, the conducted heat energy per unit time increases so that the heat can be efficiently conducted from the heat conducting section to the heat radiating section 3.

Moreover, as two fins 52 form the shapes of trapezoids of which the widths become wider from the side of the base 7 towards the side of the cover 8 along the outline form of the heat radiating section 3 more area, which is adhered to the heat radiating section 3 during the formation of integration, can be ensured. Because of the shape such as the fin 52, more heat transfer area can be ensured so that the heat generated from the power supply circuit 6 can be efficiently conducted to the heat radiating section 3 through two surfaces of both fins 52.

The power supply circuit 6, which is accommodated in the heat conducting tube 4, is electrically connected to the one-pole terminal 71 and the other-pole terminal 72 through electric wires 76 and 77. The one-pole terminal 71 of the base 7 is electrically connected to the power supply circuit 6, as shown in FIG. 6, by the wire 76 through the location between the power supply circuit 6 and the heat conducting tube 4 as a conductor made of aluminum and by soldering (not illustrated) in the location between the heat conducting tube 4 and the one-pole terminal 71 of the base 7. As comparing to the case of using only an wire connection between the power supply circuit 6 and the one-pole terminal 71 of the base 7, since the length of the wire can be shortened, and the wire 76 can be easily connected at the side of the surface 3a at the other end of the heat radiating section 3, the usability can be improved in the manufacturing process. Moreover, the power supply circuit 6 is electrically connected to the LED 12 through a wire (not illustrated) by a connector.

The light-permeable cover 8 covering the side of the LED 12 in the direction of light emission is attached to the heat radiator plate 2 located at the other end of the heat radiating section 3. The cover 8 is made of milky white glass, which is in the shape of a hemispherical enclosure. It is preferable that an anti-scattering film covers all the inner surface of the cover 8 for preventing scattering of fragments when the cover 8 fractures. This cover 8 is attached to the periphery of the heat radiator plate 2 in using an adhesive agent at the periphery of aperture of the cover 8. Moreover, the material of the cover 8 is not only limited to glass, resin such as polycarbonate may be utilized as the material.

The lighting apparatus 100, which is configured as described above, is connected to the external AC power supply by screwing the base 7 with a light-bulb socket. In this condition, when the power supply turns on, the AC current is supplied to the power supply circuit 6 through the base 7. The power supply circuit 6 supplies the determined electric potential and current energy to the LED 12 and causes the LED 12 to turn on.

According to the lighting of the LED 12, the LED 12 and the power supply circuit components 62 of the power supply circuit 6 mainly radiate heat. The heat generated from the LED 12, as described above, is conducted to the heat radiator plate 2 and the heat radiating section 3 and then radiated to the air outside of the lighting apparatus 100 from both of the heat radiator plate 2 and the heat radiating section 3. The heat generated from the power circuit components 62 of the power supply circuit 6 is conducted to the heat exchanger plate 5, then a part of the conducted heat is conducted to the heat conducting tube 4 from the heat exchanger plate 5. The heat conducted in both of the heat exchanger plate 5 and the heat conducting tube 4 is conducted to the heat radiating section 3, which is adhered closely to the heat conducting tube 4 and the fin 52, and then the heat is radiated to the air outside of the lighting apparatus 100 from the heat radiating section 3.

With regard to the lighting apparatus 100 related to the present embodiment, as described above, since the heat radiating section 3, the heat conducting tube 4 and the heat exchanger plate 5 are formed in an integrated manner, both the outer surface 4a of the heat conducting tube 4 and the fin 52 as the heat conducting section can be adhered closely to the heat radiating section 3. Therefore, the heat can be efficiently conducted from both of the heat conducting tube 4 and the heat exchanger plate 5 to the heat radiating section 3 and then the heat generated from a radiating body such as the power supply circuit 6 can be fully radiated.

As the heat radiating section 3 is provided for covering the outer surface 4a of the heat conducting section 4 accommodating the power supply circuit 6 and the portion of the fin 52 protruded from the outer surface 4a of the heat conducting tube 4 and for burying the protruded section into the heat radiating section 3, more heat transfer area with better thermal conduction can be created in the condition of adherence. Moreover, the fin 52 forms the shape of a trapezoid of which the outline corresponds to the shape of the heat radiating section 3; therefore, the heat transfer area of both the fin 52 and the heat radiating section 3 can be ensured so that the heat can be efficiently conducted to the heat radiating section 3. Accordingly, the heat can be efficiently conducted to the heat radiating section 3 from both of the heat conducting tube 4 and the heat exchanger plate 5, and the heat generated from a radiating body such as the power supply circuit 6 can be fully radiated.

The diameter of the heat conducting tube 4 and the shape of the heat exchanger plate 5 are appropriately determined for making the power supply circuit 6 close to the inner surface 4b of the heat conducting tube 4 as much as possible. Accordingly, since the power supply circuit 6 and the heat radiating section 3 are made close each other, the heat generated in the power supply circuit 6 is conducted to the surface of the heat radiating section 3 facing the power supply circuit 6 so that the efficiency of heat radiation from the heat radiating section 3 can be improved.

Since the heat radiating section 3 is made of resin, as comparing to the heat radiating section made of metal such as aluminum, trimming weight of the heat radiating section 3 and therefore the lighting apparatus 100 can be achieved. Generally, the thermal conductivity of heat radiation resin is lower than that of metal; however, as described above, since the heat radiating section 3, the heat conducting tube 4 and the heat exchanger plate 5 are formed in an integrated manner and both of the outer surface 4a of the heat conducting tube 4 and the fin 52 are made closely to the heat radiating section 3, along with trimming weight of the lighting apparatus 100, the heat generated in a radiating body such as the power supply circuit 6 is fully radiated. Accordingly, the power supply circuit components 62 of the power supply circuit 6 can be cooled down to the necessary temperature for ensuring the predetermined performance.

Since the heat radiating section 3, the heat conducting tube 4, the heat exchanger plate 5 and the base 7 are formed in an integrated manner, in other words, the heat radiating section 3 is functioned as a connecting body, utilizing fastener components such as screws is not necessary so that the configuration and the manufacturing process can be simplified, and the cost can be reduced. Since the heat radiating section 3 is made of resin, fabricating the heat radiating section 3 and the integral molding member including the heat radiating section 3 can be easily processed by injection molding. Particularly, as comparing to the heat radiating section 3 made of aluminum die-cast, the necessary energy for fabricating a heat radiating section during the manufacturing process can be greatly reduced; therefore, this manufacturing process contributes to the energy saving.

Furthermore, the heat radiating section 3 is made of electrical insulating material. When a conductor is utilized in the heat radiating section 3, it is necessary to prevent an electric shock through an electrical insulating member between the heat radiating section 3 and the base 7 connected to the external power supply. Since the heat radiating section 3 is made of electrical insulating material, utilizing the electrical insulating member is not necessary so that the number of components can be reduced and weight reduction and miniaturization can be achieved.

With regard to a light-bulb type lighting apparatus, a socket to which an existing incandescent light bulb is attached is often thin corresponding to the shape of the incandescent light bulb. When an electrical insulator member is installed on a light bulb having a heat radiating section made of an electrical conductor, the periphery of a base becomes thicker because of the electrical insulator member provided between the base and the heat radiating section; therefore, the light bulb cannot be fitted to an existing light socket. With regard to the lighting apparatus 100 related to the present embodiment, as the heat radiating section 3 is made of electrical insulating material, since utilizing an electric insulator member is not necessary, the thinner portion fitted to a socket can be formed so that the light bulb can be fitted to an existing light socket.

With regard to the embodiment described above, the heat conducting tube 4 and the heat exchanger plate 5 as the heat conduction section are installed separately; however, both members may be formed in an integrated manner. Additionally, either the heat conducting tube 4 or the heat exchanger plate 5 may be formed individually.

With regard to the embodiment described above, the heat conducting tube 4, the heat exchanger plate 5 and the base 7 as the heat conducting section are formed with the heat radiating section 3 in an integration manner by using metal mold; however, the heat conducting section may be thermally connected to the heat radiating section 3 after the heat radiating section 3 is formed individually. At that time, the heat radiating section 3 forms a shape that allows the heat conducting section to be thermally connected to the formed heat radiating section. Particularly, by forming a heat radiating section having a cavity inside with pluggability to an inserted heat conducting section in which the heat conducting tube 4 and the heat exchanger plate 5 with regard to the first embodiment are engaged each other, the heat conducting section can be thermally connected to the heat radiating section after the formation. Additionally, the base 7 may be fixed to the heat radiating section 3 after formation by screws or the like.

### Embodiment 2

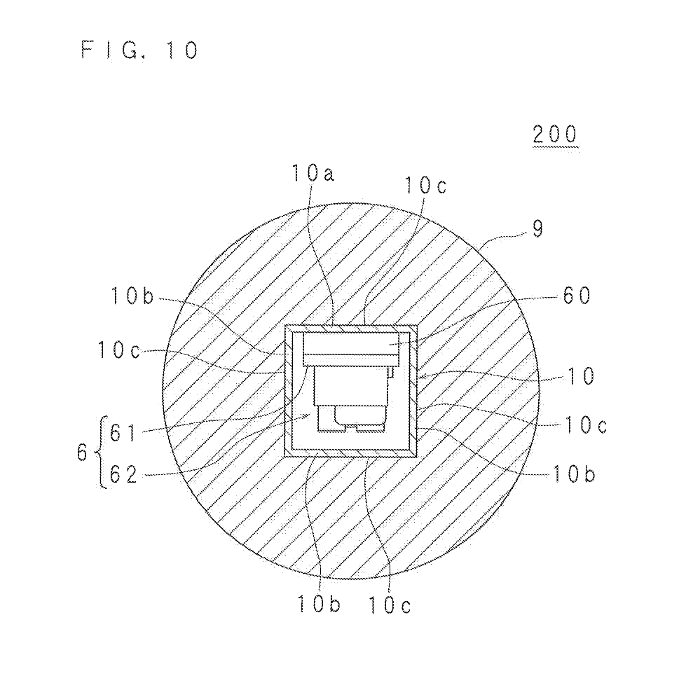

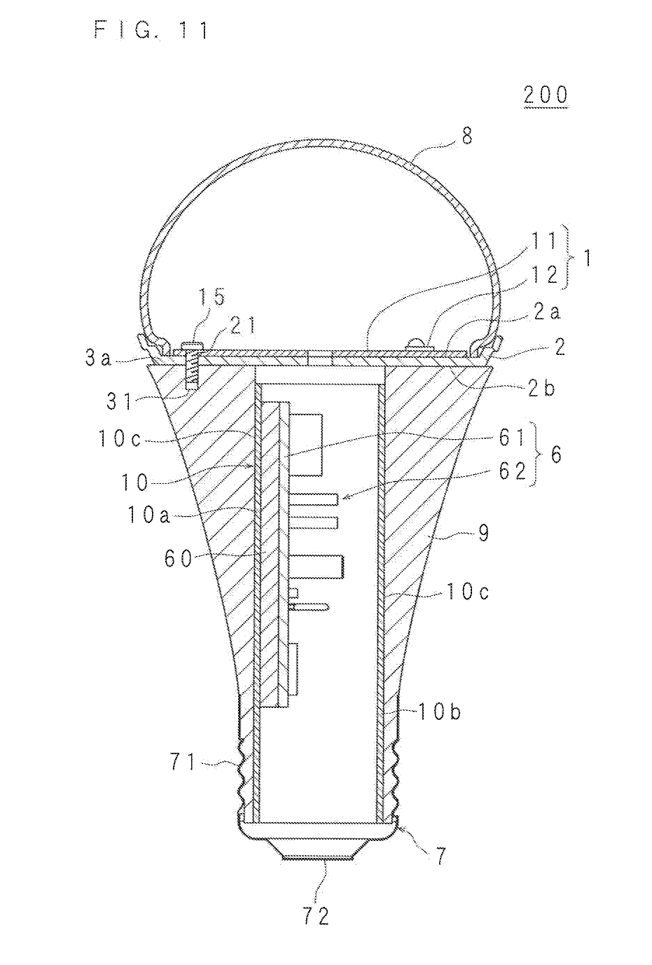

FIG. 10 is a schematic cross sectional view of a lighting apparatus 200 related to the second embodiment of the present invention. FIG. 11 is a schematic longitudinal sectional view of the lighting apparatus 200 related to the second embodiment of the present invention. The same reference numbers are appended to the corresponding configuration in the first embodiment, so the detailed description is omitted.

A heat conducting tube 10, which functions as a heat conducting section for conducting the heat generated from a heating body such as an LED 12 and a power supply circuit 6 to a heat radiating section 9, is buried in a heat radiating section 9. The heat conducting tube 10 is a heat conductor made of, for example, metal such as aluminum.

The heat conducting tube 10 has a shape of a square tube that can accommodate the power supply circuit 6 inside. The heat conducting tube 10 includes a connecting section 10a having a surface of four surfaces constituting the heat conducting tube 10, which is thermally connected to the power supply circuit 6, inside the heat conducting tube 10, and a conducting unit 10b for receiving the heat, which is generated from the power supply circuit 6, from the connecting section 10a and then conducting the heat to the heat radiating section 9. The conducting unit 10b is composed of a member having two surfaces adjacent to both ends of the connecting section 10a and a surface opposite to the connecting section 10a.

As shown in both of FIG. 10 and FIG. 11, with regard to the power supply circuit 6, a power supply circuit substrate 61 installing power supply circuit components 62 is thermally connected through a thermal conduction sheet 60 to an inner surface of the heat conducting tube 10 at the connecting section 10a.

The formation method of the heat radiating section 9 is described. Firstly, the heat conducting tube 10 is fitted into a base 7 for aligning the periphery at one end of the heat conducting tube 10 in the longitudinal direction to the inside of the base 7 (see FIG. 11). The width and thickness of both the connecting section 10a and the conducting section 10b constituting the heat conducting tube 10 can be any dimensions even when one end of the heat conducting tube 10 in the longitudinal direction can be fitted into the base 7 and the power supply circuit 6, which is thermally connectable to the connecting section 10a, is accommodated inside the heat conducting tube 10. Next, while holding the state of fitting the heat conducting tube 10 into the base 7, the heat conducting tube 10 is fitted to a metal mold corresponding to the shape of the heat radiating section 9. Then, the above-described heat radiation resin in molten state is flowed into the metal mold by using an injection molding machine and then the heat radiation resin is solidified.

The heat radiation resin is flowed into the metal mold so that the heat conducting tube 10 is buried in the heat radiating section 9 with covering the outer surface 10c of the heat conducting tube 10 and a gap between the inner surface of the base 7 and the outer surface 10c of the heat conducting tube 10 is filled, and then the heat radiating section 9 is formed. FIG. 11 is a longitudinal sectional view illustrating a state of integrating the heat conducting tube 10 and the base 7 into the heat radiating section 9 after the solidification of the heat radiation resin.

By configuring the shape of the heat conducting tube 10 as a heat conducting section to be such as a square tube having a surface thermally connectable to the power supply circuit directly inside the heat conducting section, the member such as the heat exchanger plate 5 thermally connected to the power supply circuit 6 in the first embodiment can be reduced, and the configuration of the heat conducting section can be simplified. The heat conducting section like the connecting section 10a is thermally connected to the power supply circuit 6, and has a shape where both the heat radiating section 9 and the outer surface 10c are made close each other directly. Since layer of air is not filled between the power supply circuit 6 as a heating body and the heat radiating section 9, the heat resistance between the power supply circuit 6 and the heat radiating section 9 can be decreased, and the heat can be conducted in the short distance. Therefore, the heat generated from the power supply circuit 6 can be promptly conducted to the heat radiating section 9 and then the heat can be efficiently radiated from the heat radiating section 9.

With regard to the second embodiment, the heat generated from the power supply circuit 6 is conducted to the connecting section 10a through the thermal conduction sheet 60 and conducted to the heat radiating section 9 from the connecting section 10a. Alternatively, the heat is conducted to the conducting section 10b from the connecting section 10a and conducted to the heat radiating section 9 from the conducting section 10b. And then the heat is radiated to outside air from the heat radiating section 9. As the conducting section 10b is installed, the heat resistance of the heat conducting section is decreased, and the heat conducted from the power supply circuit 6 to the connecting section 10a is dissipated to the conducting section 10b; therefore, temperature rise of the power supply circuit 6 can be suppressed.

With regard to the shape of the heat conducting tube 10, forming the shape of a square tube is not necessary. The heat conducting tube 10 may have a surface like the connecting section 10 that is thermally connectable to the power supply circuit 6, and have a shape such that it is thermally connectable to the heat radiating section 9 at the outer surface. For example, the heat conducting tube 10 may have a shape of pentagonal tube. Alternatively, the heat conducting tube 10 may have a shape wherein a part of inner surface of the cylindrical tube as the connecting section with a substantially plane surface is thermally connected to the power supply circuit 6 and an arc section other than the connecting section is functioned as the conducting section. Moreover, at the outer surface of the heat conducting tube 10, a protruding portion such as the fin 52 in the first embodiment may be installed so as to widen the heat transfer area in the heat conducting section.

As similar to the first embodiment, in the manufacturing method, the heat conducting section may be thermally connected to the heat radiating section 9 after the heat radiating section 9 is formed individually. At that time, the heat radiating section 9 forms a shape that allows the heat conducting section to be thermally connected to the formed heat radiating section. Particularly, by forming a heat radiating section having a cavity inside with pluggability to the inserted heat conducting tube 10 of the second embodiment, the heat conducting section can be thermally connected to the heat radiating section after the formation. Alternatively, the heat radiating section 9 may be formed in a method wherein the heat conducting tube is sandwiched by a pair of heat radiating sections formed in advance to be fixed. Additionally, the base 7 may be fixed to the heat radiating section 9 after formation by screws or the like.

Moreover, with regard to the embodiment of the lighting apparatus related to the present invention, when the heat radiating section is formed in advance, the heat conducting section such as the heat conducting tube 4, the heat exchanger plate 5 and the heat conducting tube 10 described in the first embodiment and the second embodiment is not utilized; however, a heat conduction member having elasticity and good heat conductivity such as the thermal conduction sheet 60 may be utilized as a heat conducting section, and a power supply circuit may be thermally connected to a heat radiating section through the heat conducting section. In that case, weight trimming can be achieved by reducing the number of components; however, it is preferable to carry out a devise for forming the thickness of the heat radiating section to be thinner so as to improve the heat radiation.

With regard to the embodiments described above, the heat radiating sections 3 and 9 are made of resin; however, the heat radiating section may be made of the material having electrical insulating property such as ceramics. Moreover, with regard to the embodiments described above, although only the heat radiating sections 3 and 9 are made of resin, the heat radiator plate 2 may be made of resin, and the heat radiator plate 2 may be formed with the light source module 1 in an integrated manner as similar to the heat radiating sections 3 and 9.

With regard to the embodiment of the lighting apparatus related to the present invention, in order to improve the efficiency of heat radiation from the heat radiating section, it is preferable to form a heat radiating film with better thermal radiative property on the outer surface of the heat radiating section. The heat radiating film, for example, includes a first ceramic film provided on the outer surface of the heat radiating section, and a second ceramic film which is provided on the surface of the first ceramic film and of which the wavelength distribution of infrared emissivity is different from that of the first ceramic film.

The first ceramic film is formed by applying a coating material including a heat radiative substance with high infrared emissivity (emissivity in the wavelength of infrared rays) on the outer surface of the heat radiating section and hardening it. For example, aluminum oxide is utilized as the heat radiative substance included in the coating material of the first ceramic film. Carbon black and metallic oxide material such as titanium oxide and silicon dioxide may also be utilized as the heat radiative substance used in the first ceramic film. The thickness of the first ceramic film is appropriately limited according to the temperature of a heating body.

The second ceramic film is formed by applying a coating material including a heat radiative substance with an efficiency of heat radiation, which is different from the efficiency of heat radiation of aluminum oxide utilized as the heat radiative substance of the first ceramic material, on the surface of the first ceramic film, and hardening it. For example, titanium oxide of metallic oxide material is utilized as the heat radiative substance included in the coating material of the second ceramic film. The heat radiative substance utilized in the second ceramic film is not limited to titanium oxide. The heat radiative substance having different efficiency of heat radiation from the aluminum oxide used as the heat radiative substance of the first ceramic film may also be utilized. Metallic oxide material or carbon black of which the efficiency of heat radiation is different from that of aluminum oxide may also be utilized.

It is preferable that the first ceramic film and the second ceramic film are sintered in 110° C. and hardened after application. Thanks to sintering, the heat radiating film is closely adhered to a main body of the heat radiating section and the application degree can be improved. Since the molecules in the heat radiating film are tightly bonded, the efficiency of heat radiation through eradiation can be improved.

Since the heat radiating film is formed on the surface of the heat radiating section, infrared rays are easily radiated from the heat radiating film. Therefore, along with convective heat transfer from the heat radiating section, the heat transfer owing to the heat radiation from the surface of the heat radiating section can be efficiently performed, and the heat conducted from a heating body such as an LED and a power supply circuit can be efficiently radiated to outside.

With regard to the embodiment described above, the power supply circuit 6 accommodated in the heat conducting tube 4 or the heat conducting tube 10 is described as a heating body; however, in a lighting apparatus with lighting control function for adjusting the intensity and/or chromaticity of LED, a control section for lighting control can also be a heating body. In such a case, like the power supply circuit 6 described in the above embodiments, a control circuit substrate is mounted on the connecting plate 51 of the heat exchanger plate 5 or the connecting section 10a of the heat conducting tube 10, the heat generated from the control section can be efficiently conducted to the heat radiating section 3.

With regard to the embodiments described above, a surface-mount LED is utilized as the light source; however, other different types of LED and EL (Electro Luminescence) may also be utilized as the light source.

With regard to the embodiments described above, a light-bulb type lighting apparatus attached to a light-bulb socket is described; however, other types of lighting apparatuses such as a downlight may also be applicable. When the downlight is applied in the invention, a base is not necessary, and a heat conducting section and a heat radiating section are formed in an integrated manner. Furthermore, the present invention may utilize an apparatus including a heating body other than the lighting apparatus. Besides, it is needless to say that the scope of matter described in claims can be practiced by other modified modes.

As this invention may be embodied in several forms without departing from the spirit of essential characteristics thereof, the present embodiments are therefore illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1-7. (canceled)

8. A lighting apparatus comprising:
a light source;
a power supply circuit supplying power to said light source;
a heat radiating section, made of electrical insulating material, radiating heat from said power supply circuit accommodated inside to outside air; and
a heat conducting section conducting heat from said power supply circuit to said heat radiating section,
wherein said heat radiating section and said heat conducting section are thermally connected.

9. The lighting apparatus according to claim 8,
wherein at least a part of said heat conducting section is buried in said heat radiating section.

10. The lighting apparatus according to claim 8, further comprising a base,
wherein said base is formed integratedly with said heat radiating section.

11. The lighting apparatus according to claim 8,
wherein said heat conducting section comprises a connecting section thermally connected to said power supply circuit and a conducting unit conducting heat from said power supply circuit to said heat radiating section.

12. The lighting apparatus according to claim 8,
wherein said heat conducting section comprises: a tubular section accommodating said power supply circuit inside; a connecting section installed on said tubular section and thermally connected to said power supply circuit; and a protruding section protruded on the outer surface of said tubular section, and
wherein said heat radiating section covers both the outer surface of said tubular section and said protruding section.

13. The lighting apparatus according to claim 8,
wherein said heat conducting section comprises a tubular section accommodating said power supply circuit inside and is thermally connected to said power supply circuit on the inner surface of said tubular section, and
wherein said heat radiating section covers the outer surface of said heat conducting section.

14. A lighting apparatus comprising:
a heating body including a light source and/or a power supply circuit;
a heat radiating section radiating heat from said heating body; and
a heat conducting section conducting heat from said heating body to said heat radiating section,
wherein at least a part of opposite surfaces of said heat conducting section and said heat radiating section is thermally connected so as to perform efficient heat conduction.

15. The lighting apparatus according to claim 14,
wherein at least a part of said heat conducting section is buried in said heat radiating section.

16. The lighting apparatus according to claim 14, further comprising a base,
wherein said base is formed integratedly with said heat radiating section.

17. The lighting apparatus according to claim 14,
wherein said heat conducting section comprises a connecting section thermally connected to said power supply circuit and a conducting unit conducting heat from said power supply circuit to said heat radiating section.

18. The lighting apparatus according to claim 14,
wherein said heat conducting section comprises: a tubular section accommodating said power supply circuit inside; a connecting section installed on said tubular section and thermally connected to said power supply circuit; and a protruding section protruded on the outer surface of said tubular section, and
wherein said heat radiating section covers both the outer surface of said tubular section and said protruding section.

19. The lighting apparatus according to claim 14,
wherein said heat conducting section comprises a tubular section accommodating said power supply circuit inside and is thermally connected to said power supply circuit on the inner surface of said tubular section, and
wherein said heat radiating section covers the outer surface of said heat conducting section.
